(19) United States
(12) Patent Application Publication
(10) Pub. No.: US 2007/0285173 A1
(43) Pub. Date: Dec. 13, 2007

(54) Frequency compensating circuit including a current-mode active capacitor and control circuit

(76) Inventors: Sang-Hwa Jung, Seoul (KR); Dong-Hee Kim, Gyeonggi-do (KR); Jong-Tae Hwang, Seoul (KR)

Correspondence Address: SIDLEY AUSTIN LLP, 555 CALIFORNIA STREET, SUITE 2000, SAN FRANCISCO, CA, 94104-1715, US

(21) Appl. No.: 11/805,476

(22) Filed: May 23, 2007

(30) Foreign Application Priority Data
May 24, 2006 (KR) 10-2006-46489

(51) Int. Cl. H03F 3/191

(52) U.S. Cl. 330/302

(57) ABSTRACT

A frequency compensating circuit having a current-mode active capacitor is disclosed. The frequency compensating circuit includes a first transconductance amplifier and a current-mode active capacitor. The first transconductance amplifier amplifies a feedback voltage signal in a current mode to provide the amplified voltage to a first node. The current-mode active capacitor is coupled to the first node. Accordingly, the frequency compensating circuit may occupy a small area in the semiconductor integrated circuit because the frequency compensating circuit uses a capacitor having a small capacitance.

### CROSS-REFERENCE TO RELATED APPLICATIONS

This application claims priority under 35 USC §119 to Korean Patent Application No. 10-2006-46489, filed on May 24, 2006, in the Korean Intellectual Property Office, incorporated herein in its entirety by reference.

### BACKGROUND

1. Field of the Invention

The present invention relates to a frequency compensating circuit, and more particularly to a frequency compensating circuit having an active capacitor.

2. Description of the Related Art

FIG. 1 is a circuit diagram illustrating a conventional control circuit 100. In general, the control circuit 100 drives a switching transistor included in a DC-DC converter and controls an output voltage of the DC-DC converter. The control circuit 100 generates a gate control signal and provides the gate control signal to a gate of the switching transistor.

The control circuit 100 can include a frequency compensating circuit 110, a comparator 120, RS-type flip-flop 130, and a buffer 140.

The frequency compensating circuit 110 can include a transconductance amplifier 111, a first feedback resistor RF1, a second feedback resistor RF2, a compensating resistor RC1, and a compensating capacitor CC1. The comparator 120 can compare an output signal VC of the frequency compensating circuit 110 with a sensing voltage VSEN1. Sensing voltage VSEN1 is the voltage into which a switching current is converted. The output signal of the comparator 120 can be applied to a reset terminal R of the RS-type flip-flop 130, and a clock signal CLK can be applied to a set terminal S of the RS-type flip-flop 130. The buffer 140 can buffer the output signal of the RS-type flip-flop 130 to generate a gate driving signal VG. The gate driving signal VG may be applied to a gate of a switching transistor, included in a DC-DC converter.

FIG. 2 is a graph illustrating voltage gain versus frequency of a frequency compensating circuit 110, included in the control circuit 100 of FIG. 1. At low frequencies the voltage gain AV can assume the approximate value gm·ro. At frequencies above a pole frequency fp the voltage gain AV can decrease. Above a zero frequency fz, higher than the pole frequency fp, the voltage gain AV can level off at a value gm·RC1. The pole frequency fp may be represented as fp=1/(2π·ro·CC1), and the zero frequency fz may be represented as fz=1/(2π·ro·CC1). Here, gm denotes a transconductance of the transconductance amplifier 111, and ro denotes an output resistance of the transconductance amplifier 111.

The compensating capacitor CC1 included in the frequency compensating circuit 110 may have a capacitance of a few nF. A lot of chip area is needed to implement a capacitor having such a large capacitance in a semiconductor integrated circuit. Therefore, in the conventional art, the compensating capacitor CC1 was formed outside of the chip, or semiconductor integrated circuit.

However, certain applications, such as hand-held electronic devices, have a limited area to mount parts. Therefore, there is a need to include the large capacitance compensating capacitor on a small chip area inside the semiconductor integrated circuit.

### SUMMARY

Briefly and generally, some embodiments of the present invention include a current-mode active capacitor having a capacitance multiplying effect.

Some embodiments include a frequency compensating circuit having a current-mode active capacitor.

Some embodiments include a control circuit having a current-mode active capacitor.

Some embodiments include a DC-DC converter having a current-mode active capacitor.

Some embodiments include a method of frequency compensation using a current-mode active capacitor.

Some embodiments include a method of driving gates using a current-mode active capacitor.

Some embodiments include a current-mode active capacitor having a first capacitor, a first resistor, and a transconductance amplifier.

The first capacitor is coupled between a first node and a second node. The first resistor is coupled between the second node and a third node. The transconductance amplifier has a first input terminal coupled to the second node, a second input terminal coupled to the third node, and an output terminal coupled to the first node.

In some embodiments a ground voltage is applied to the third node.

In some embodiments an equivalent circuit of the current-mode active capacitor may have an equivalent capacitor and an equivalent resistor. A capacitance of the equivalent capacitor is (1+gm·RS) CF, and a resistance of the equivalent resistor is RS/(1+gm·RS). Here, gm denotes a transconductance of the transconductance amplifier, RS denotes a resistance of the first resistor, and CF denotes a capacitance of the first capacitor.

Some embodiments include a current-mode active capacitor having a first resistor, a first capacitor, and a transconductance amplifier.

The first resistor is coupled between a first node and a second node. The first capacitor is coupled between the second node and a low supply voltage. The transconductance amplifier has a first input terminal coupled to the first node, a second input terminal coupled to the second node, and an output terminal coupled to the first node.

Some embodiments include a frequency compensating circuit having a first transconductance amplifier and a current-mode active capacitor.

The first transconductance amplifier amplifies a feedback voltage signal in a current mode to provide the amplified voltage to a first node. The current-mode active capacitor is coupled to the first node.

In some embodiments the current-mode active capacitor may include a first capacitor, a first resistor, and a transconductance amplifier.

The first capacitor is coupled between a first node and a second node. The first resistor is coupled between the second node and a third node. The transconductance amplifier has a first input terminal coupled to the second node, a second input terminal coupled to the third node, and an output terminal coupled to the first node.

In some embodiments the current-mode active capacitor may include a first resistor, a first capacitor, and a transconductance amplifier.

The first resistor is coupled between a first node and a second node. The first capacitor is coupled between the second node and a low supply voltage. The transconductance amplifier has a first input terminal coupled to the first node, a second input terminal coupled to the second node, and an output terminal coupled to the first node.

In some embodiments the frequency compensating circuit may further include a resistor coupled between the first node and the current-mode active capacitor.

In some embodiments the feedback voltage signal may be generated based on an output signal of a DC-DC converter.

Some embodiments include a control circuit having a frequency compensating circuit, a current detecting circuit, a comparator, and a pulse-width modulating circuit.

The frequency compensating circuit has a current-mode active capacitor, amplifies a feedback voltage signal to generate a compensating voltage signal, and provides the compensating voltage signal to a first node. The current detecting circuit detects a current flowing through a switching transistor to generate a first detecting voltage signal. The comparator compares the compensating voltage signal with the first detecting voltage signal to generate a comparing signal. The pulse-width modulating circuit generates a gate driving signal based on a clock signal and the comparing signal.

In some embodiments the pulse-width modulating circuit may have a flip-flop.

In some embodiments the control circuit may further include a buffer that buffers an output signal of the pulse-width modulating circuit to generate the gate driving signal.

In some embodiments the feedback voltage signal may be generated based on an output signal of a DC-DC converter.

Some embodiments include a DC-DC converter having an input node to which a DC input voltage is applied, a switching transistor, a diode, an inductor, a first capacitor, and a control circuit.

The switching transistor is coupled between the input node and a first node, and is driven in response to a gate driving signal. The diode has a cathode coupled to the first node and an anode coupled to a first supply voltage. The inductor is coupled between the first node and an output node. The first capacitor is coupled between the output node and the first supply voltage. The control circuit includes a frequency compensating circuit that has a current-mode active capacitor. The control circuit generates the gate driving signal in response to a current flowing through the switching transistor, a voltage of the output node, and a clock signal.

In some embodiments the control circuit includes a frequency compensating circuit, a current detecting circuit, a comparator, and a pulse-width modulating circuit.

The frequency compensating circuit has a current-mode active capacitor, amplifies a feedback voltage signal to generate a compensating voltage signal, and provides the compensating voltage signal to a first node. The current detecting circuit detects a current flowing through a switching transistor to generate a first detecting voltage signal. The comparator compares the compensating voltage signal with the first detecting voltage signal to generate a comparing signal. The pulse-width modulating circuit generates a gate driving signal based on a clock signal and the comparing signal.

Some embodiments include a method of frequency compensation, the method comprising amplifying a feedback voltage signal in a current mode to provide the amplified voltage to a first node, generating an active capacitance in the current mode, and providing the active capacitance to the first node.

Some embodiments include a method of driving gates, the method comprising generating an active capacitance in the current mode, amplifying a feedback voltage signal to generate a compensating voltage signal based on the active capacitance, detecting a current flowing through a switching transistor to generate a first detecting voltage signal, comparing the compensating voltage signal with the first detecting voltage signal to generate a comparing signal, and generating a gate driving signal based on a clock signal and the comparing signal.

Therefore, in some embodiments the current-mode active capacitor may generate an equivalent capacitor having a large capacitance using a capacitor having a small capacitance.

### BRIEF DESCRIPTION OF THE DRAWINGS

FIG. 1 is a circuit diagram illustrating a conventional control circuit.

FIG. 2 is a graph illustrating voltage gain versus frequency of a frequency compensating circuit included in the control circuit of FIG. 1.

FIG. 3 is a circuit diagram illustrating a current-mode active capacitor.

FIG. 4 is a circuit diagram illustrating an equivalent circuit of the current-mode active capacitor shown in FIG. 3.

FIG. 5 is a circuit diagram illustrating a current-mode active capacitor.

FIG. 6 is a circuit diagram illustrating a frequency compensating circuit including the current-mode active capacitor of FIG. 3.

FIG. 7 is a graph illustrating voltage gain versus frequency of a frequency compensating circuit of FIG. 6.

FIG. 8 is a circuit diagram illustrating a frequency compensating circuit including the current-mode active capacitor of FIG. 5.

FIG. 9 is a DC-DC converter including the frequency compensating circuit of FIG. 6.

FIG. 10A and FIG. 10B are graphs illustrating waveforms of an output signal of a frequency compensating circuit.

FIG. 11A and FIG. 11B are graphs illustrating waveforms of an output signal of a buck converter.

FIG. 12 is a DC-DC converter including the frequency compensating circuit of FIG. 8.

### DETAILED DESCRIPTION

Embodiments of the present invention now will be described more fully with reference to the accompanying drawings. However, the ideas can be embodied in many analogous systems, combinations and arrangements, all of which will be recognized by persons or ordinary skill in the art as belonging to the scope of the invention.

Like reference numerals refer to like elements throughout this application. The term “and/or” includes any and all combinations of one or more of the associated listed items. When an element is referred to as being “connected” or “coupled” to another element, it can be directly connected to the other element, or it can be coupled to the other element through intervening elements. Embodiments in which an element is referred to as being “directly connected” to another element, contain no intervening elements. Other words used to describe the relationship between elements should be interpreted in a like fashion (e.g., “between” versus “directly between,” “adjacent” versus “directly adjacent,” etc.).

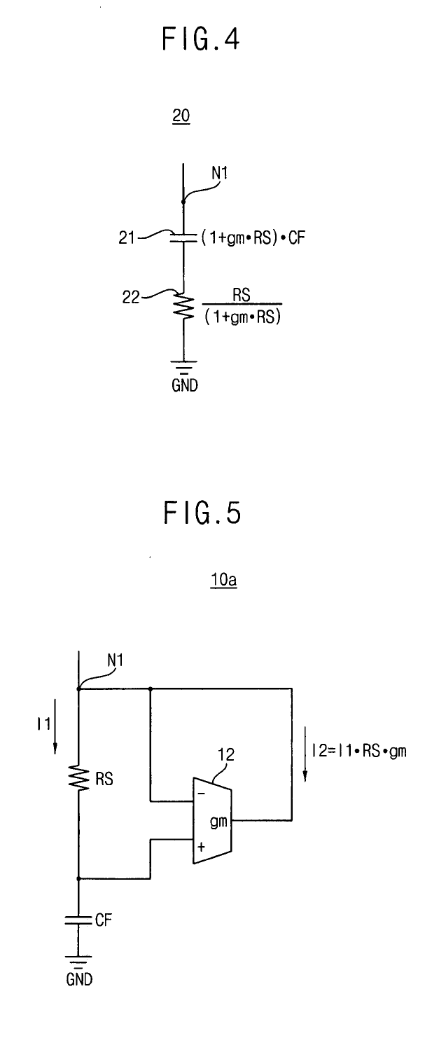

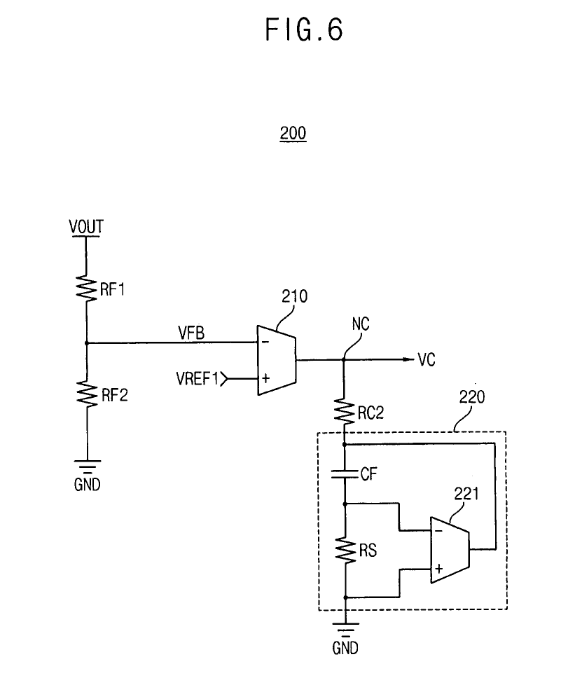

FIG. 3 illustrates a circuit diagram of a current-mode active capacitor 10. FIG. 4 illustrates a circuit diagram of an equivalent circuit 20 of the current-mode active capacitor 10 shown in FIG. 3.

FIG. 3 illustrates that the current-mode active capacitor 10 can include a first capacitor CF, a first resistor RS, and a transconductance amplifier 12. The first capacitor CF can have a first terminal coupled to a first node N1. The first resistor RS can have a first terminal coupled between a second terminal of the first capacitor CF and the ground voltage GND. The transconductance amplifier 12 has a first input terminal coupled to the second terminal of the first capacitor CF, a second input terminal coupled to the ground voltage, and an output terminal coupled to the first node N1.

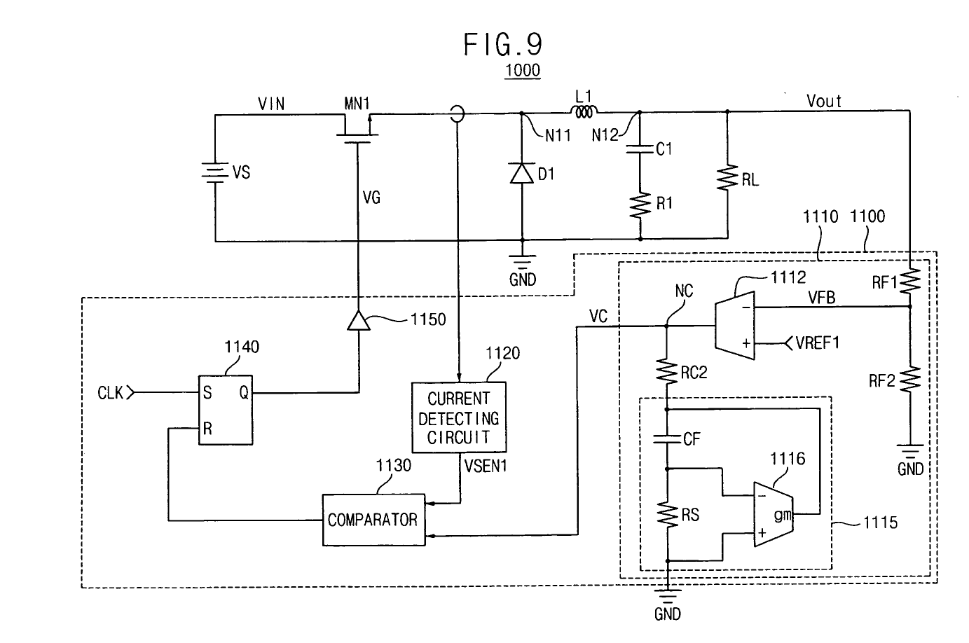

FIG. 7 illustrates an operation of the current-mode active capacitor 10. A transconductance of the transconductance amplifier 12 is denoted by gm, an output resistance by ro, and a current flowing through the first capacitor CF by I1. With these notations a current I2 flowing through the output terminal of the transconductance amplifier 12 may be expressed as I2=I1·RS·gm.

As illustrated in FIG. 4, a capacitance Ceq of an equivalent capacitor 21 may be expressed as Ceq=(1+gm·RS) CF, and a resistance Req of the equivalent resistor 22 may be expressed as Req=RS/(1+gm·RS).

For example, when gm=200·10⁻⁶ A/V, CF=10 pF, and RS=414 kΩ, the capacitance Ceq of the equivalent capacitor 21 is about 830 pF and the resistance Req of the equivalent resistor 22 is about 5 kΩ.

Therefore, the current-mode active capacitor 10 shown in FIG. 3 exhibits an equivalent capacitance of about 830 pF and an equivalent resistance of about 5 kΩ, using only a capacitance of 10 pF and a resistance of 414 kΩ. Therefore, the current-mode active capacitor 10 shown in FIG. 3 can operate as a capacitance multiplier.

As referred to earlier, it is hard to implement a capacitor having a capacitance of 830 pF in a semiconductor integrated circuit because such a capacitor occupies a large area in the semiconductor integrated circuit. In contrast, the current-mode active capacitor 10 shown in FIG. 3 uses only a capacitor having a capacitance of 10 pF as a frequency compensating capacitor. Therefore, the current-mode active capacitor 10 shown in FIG. 3 occupies a small area when implemented in the semiconductor integrated circuit. Accordingly, it is easy to include the current-mode active capacitor 10 shown in FIG. 3 in a semiconductor integrated circuit.

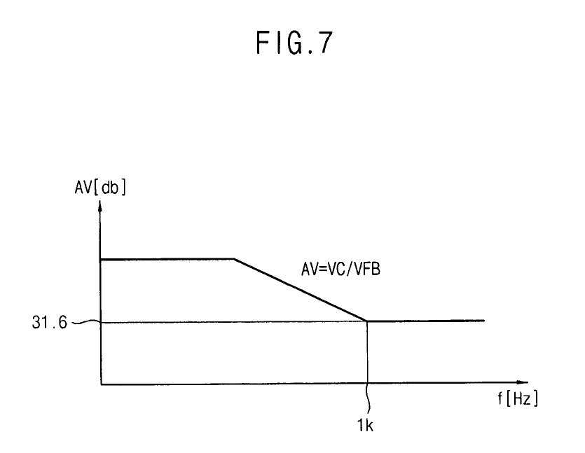

FIG. 5 illustrates an embodiment of a circuit diagram of a current-mode active capacitor 10a. The current-mode active capacitor 10a can include a first capacitor CF, a first resistor RS, and a transconductance amplifier 12. The first resistor RS can have a first terminal coupled to a first node N1. The first capacitor CF can have a first terminal coupled between a second terminal of the first resistor RS and the ground voltage GND. The transconductance amplifier 12 can have a first input terminal coupled to the first node N1, a second input terminal coupled to a second terminal of the first resistor RS, and an output terminal coupled to the first node N1.

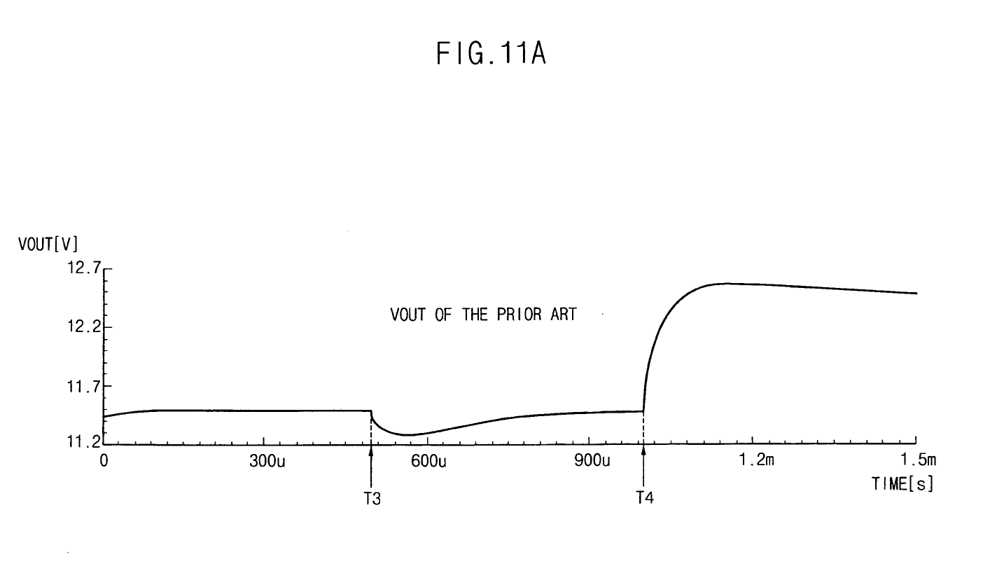

The current-mode active capacitor 10a can operate in a similar way to the current-mode active capacitor 10, as illustrated in FIG. 10. The current-mode active capacitor 10a can have a similar equivalent circuit as the equivalent circuit 20 shown in FIG. 4. In particular, a capacitance Ceq of the equivalent capacitor 21 may be expressed as Ceq=(1+gm·RS) CF, and a resistance of the equivalent resistor 22 may be expressed as Req=RS/(1+gm·RS). When a value of RS is high enough, the resistance Req of the equivalent resistor 22 may be approximated as 1/gm.

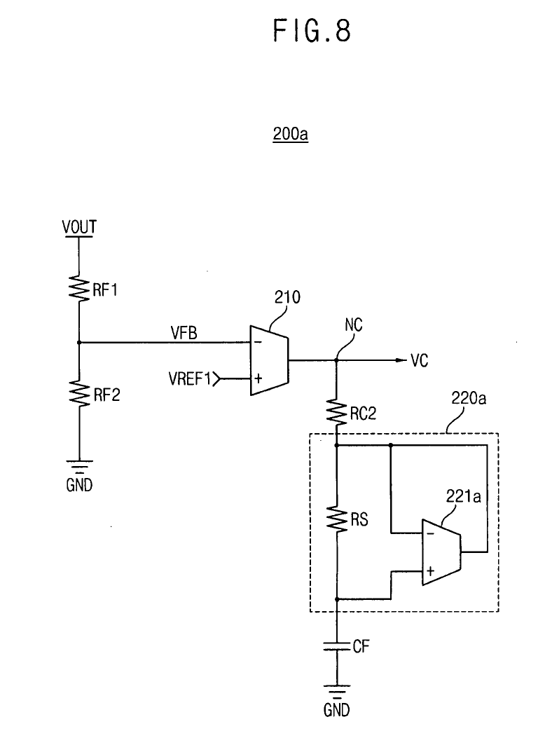

FIG. 6 illustrates a circuit diagram of a frequency compensating circuit 200 including the current-mode active capacitor 10 of FIG. 3. The frequency compensating circuit 200 can include first transconductance amplifier 210, a first resistor RC2, and a current-mode active capacitor 220. The feedback voltage VFB may be an output voltage VOUT of a DC-DC converter that is divided by resistors RF1 and RF2.

The first transconductance amplifier 210 can amplify a difference between a feedback voltage signal VFB and a reference voltage VREF1 in a current mode to provide an amplified voltage to a first node NC. The first resistor RC2 and the current-mode active capacitor 220 can compensate for a frequency characteristic of the voltage VC at the first node NC. A first terminal of the first resistor RC2 can be coupled to the first node NC, and the current-mode active capacitor 220 can be coupled between a second terminal of the first resistor RC2 and the ground voltage GND.

The current-mode active capacitor 220 can have an analogous structure as the current-mode active capacitor 10 shown in FIG. 3. The current-mode active capacitor 220 can include a first capacitor CF, a second resistor RS, and a second transconductance amplifier 221.

The first capacitor CF can have a first terminal coupled to the second terminal of the first resistor RC2. The second resistor RS can be coupled between the second terminal of the first capacitor CF and the ground voltage GND. The transconductance amplifier 221 can have a first input terminal coupled to the second terminal of the first capacitor CF, a second input terminal coupled to the ground voltage, and an output terminal coupled to the second terminal of the first resistor RC2.

Next, an operation of the frequency compensating circuit 200 having the current-mode active capacitor 220 will be described with reference to FIG. 6 and FIG. 7.

FIG. 7 is a graph illustrating a voltage gain AV as a function of a frequency of the frequency compensating circuit 200 of FIG. 6. Denoting a transconductance of the transconductance amplifier 12 by gm, an output resistance by ro, and a current flowing through the first capacitor CF by I1, a current flowing through the output terminal of the transconductance amplifier 12 I2 may be expressed as I2=I1·RS·gm. A capacitance Ceq of the equivalent capacitor of the current-mode active capacitor 220 may be expressed as Ceq=(1+gm·RS) CF, and a resistance Req of the equivalent resistor of the current-mode active capacitor 220 may be expressed as Req=RS/(1+gm·RS). When a value of RS is high enough, the resistance Req of the equivalent resistor 22 may be expressed as 1/gm.

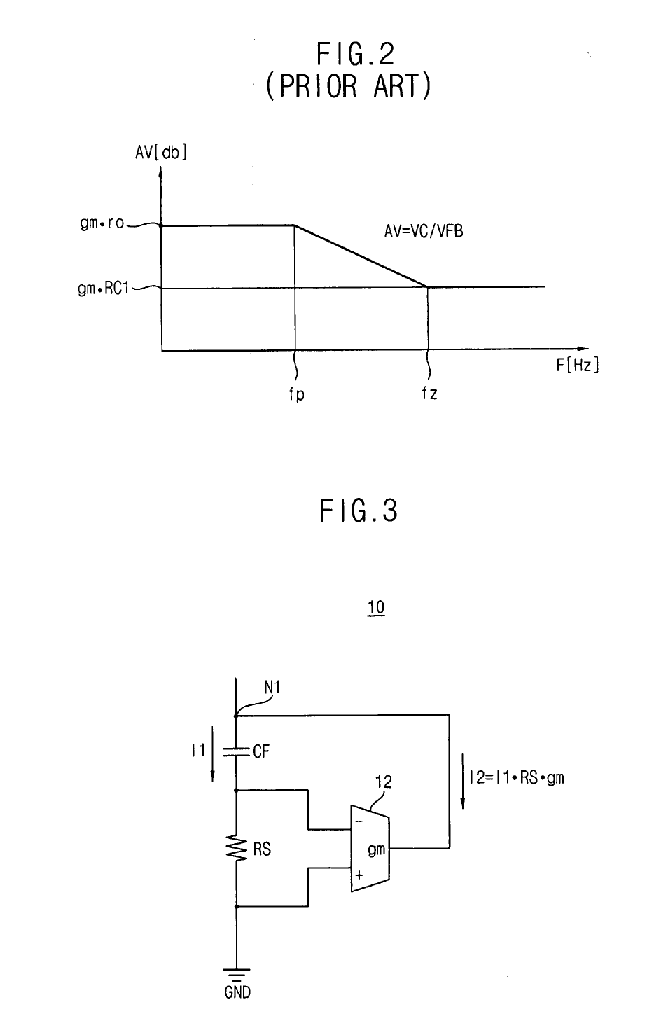

The frequency characteristics, or frequency dependence, of the frequency compensating circuit 200 is analogous to the curve shown in FIG. 2. In the frequency compensating circuit 200, when the transconductance gm of the transconductance amplifiers 210 and 221 is approximately 200·10⁻⁶ A/V, CF=10 pF, and RS=414 kΩ, the capacitance Ceq of the equivalent capacitor 21 is about 830 pF. With the equivalent capacitance Ceq of the current-mode active capacitor 220 and the equivalent resistance Req of the current-mode active capacitor 220, the zero frequency fz may be expressed as fz=1/(2π·(RC2+Req)·Ceq). The value of zero frequency fz can be, for example, about 1 kHz. The voltage gain AV at zero frequency fz may be expressed as AV=gm·(RC2+Req). The value of AV can be about 31.6 dB (=20×log 38) at fz=1 kHz.

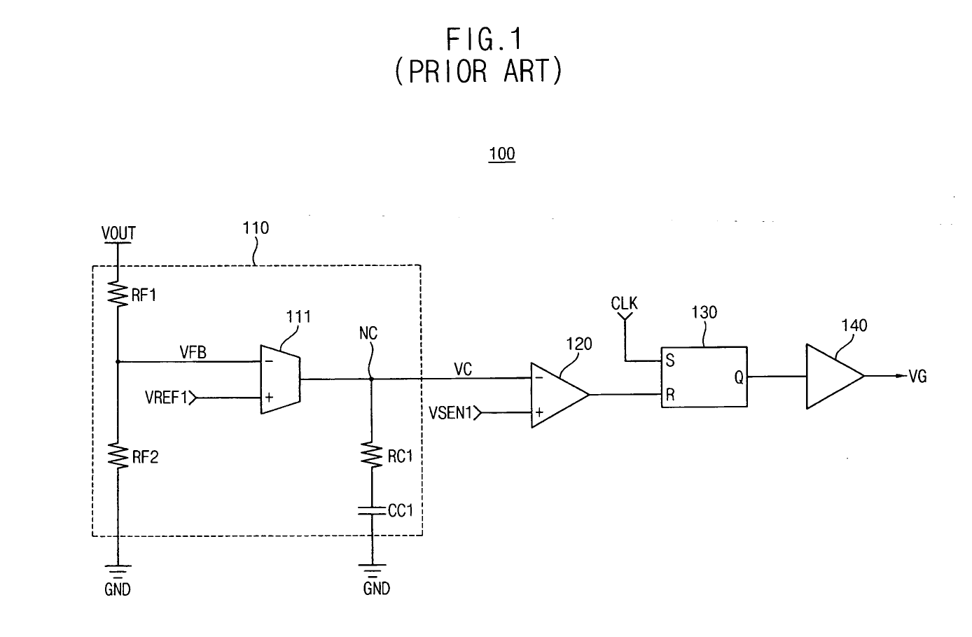

The frequency characteristics, or frequency dependence, of the frequency compensating circuit 200 of FIG. 6 can be similar to that of the frequency compensating circuit 110, shown in FIG. 1.

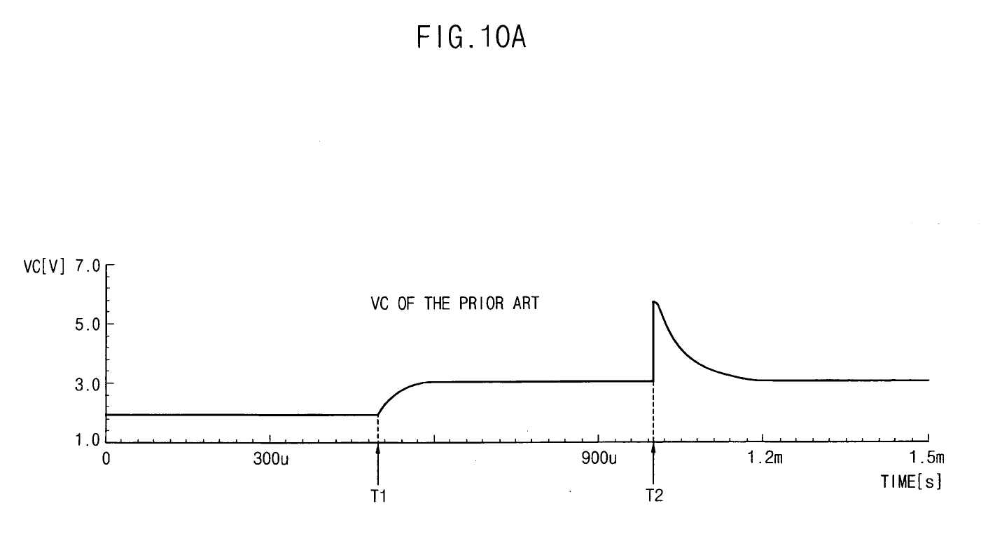

FIG. 8 illustrates a circuit diagram of a frequency compensating circuit 200a including the current-mode active capacitor 10a of FIG. 5. The frequency compensating circuit 200a can include the first transconductance amplifier 210, the first resistor RC2, and a current-mode active capacitor 220a. The feedback voltage VFB may be an output voltage VOUT of a DC-DC converter that is divided by resistors RF1 and RF2.

The first transconductance amplifier 210 can amplify a difference between a feedback voltage signal VFB and a reference voltage VREF1 in a current mode to provide the amplified voltage to the first node NC. The first resistor RC2 and the current-mode active capacitor 220a can compensate a frequency characteristic of the voltage VC at the first node NC. A first terminal of the first resistor RC2 can be coupled to the first node NC, and the current-mode active capacitor 220a can be coupled between a second terminal of the first resistor RC2 and the ground voltage GND.

The current-mode active capacitor 220a can have an analogous structure as the current-mode active capacitor 220 shown in FIG. 6. The current-mode active capacitor 220a can include the first capacitor CF, the second resistor RS, and a second transconductance amplifier 221a.

The second resistor RS can have a first terminal coupled to the second terminal of the first resistor RC2. The first capacitor CF can be coupled between the second terminal of the second resistor RS and the ground voltage GND. The transconductance amplifier 221 can have a first input terminal coupled to the first terminal of the second resistor RS, a second input terminal coupled to the second terminal of the second resistor RS, and an output terminal coupled to the first terminal of the second resistor RS.

The frequency compensating circuit 200a can operate in a similar way to the frequency compensating circuit 200 shown in FIG. 6.

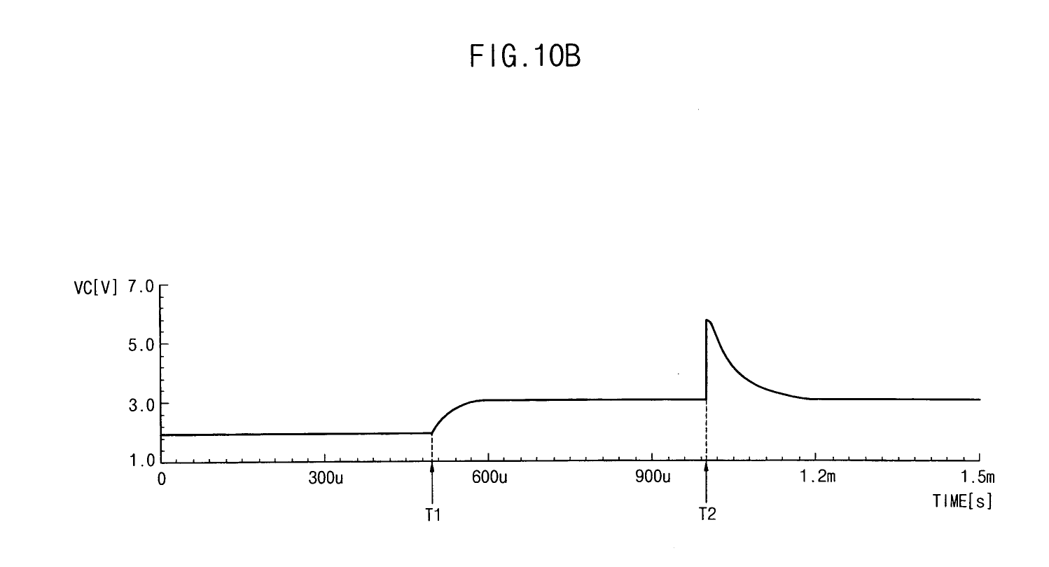

FIG. 9 is a DC-DC converter 1000 including the frequency compensating circuit 200 of FIG. 6. The DC-DC converter 1000 is a buck-type DC-DC converter that generates a DC output voltage VOUT which is lower than a DC input voltage VIN.

The DC-DC converter 1000 can include a DC voltage source VS, a switching transistor MN1, a diode D1, an inductor L1, a capacitor C1, a resistor R1, a resistor RL, and a control circuit 1100.

The switching transistor MN1 can be driven in response to a gate driving signal VG, and provides the input voltage VIN to a node N11. The diode D1 can have a cathode coupled to the node N11 and an anode coupled to the ground voltage GND. The inductor L1 can be coupled between the node N11 and an output node N12. A first terminal of the capacitor C1 can be coupled to the output node N12. The resistor R1 can be coupled between a second terminal of the capacitor C1 and the ground voltage GND. The resistor RL can be a load resistor, coupled between the output node N12 and the ground voltage GND.

The control circuit 1100 can include a frequency compensating circuit 1110, a current detecting circuit 1120, a comparator 1130, an RS-type flip-flop 1140, and a buffer 1150.

The frequency compensating circuit 1110 can be analogous to the frequency compensating circuit 200 of FIG. 6. Accordingly, the frequency compensating circuit 1110 can have a current-mode active capacitor 1115, configured to amplify a feedback voltage signal VFB to generate a compensating voltage signal VC and to provide the compensating voltage signal VC to a node NC. The current detecting circuit 1120 can detect a current flowing through the switching transistor to generate a first detecting voltage signal VSEN1. The comparator 1130 can compare the compensating voltage signal VC with the first detecting voltage signal VSEN1. An output signal of the comparator 1130 can be applied to a reset terminal of the RS-type flip-flop 1140, and a clock signal CLK can be applied to a set terminal of the RS-type flip-flop 1140. The RS-type flip-flop 1140 can perform pulse-width modulation on the output signal of the comparator 1130. The buffer 1150 can buffer an output signal of the RS-type flip-flop 1140 to generate a gate driving signal VG. The gate driving signal VG can be applied to a gate of the switching transistor MN1.

Next, an operation of the DC-DC converter 1000 will be described with reference to FIG. 9. When the switching transistor MN1 is turned on, a current corresponding to the DC input voltage VIN can flow through the inductor L1 to the capacitor C1 and the resistor RL. When the switching transistor MN1 is turned off, the diode D1 is turned on, and the current that has been flowing through the inductor L1 can flow through the loop that is comprised of the diode D1, the inductor L1, the capacitor C1, and the resistor R1. The switching transistor MN1 can operate in response to the gate driving signal VG.

The control circuit 1100 can include the frequency compensating circuit 1110 that has the current-mode active capacitor 1115, and generate the gate driving signal VG in response to a current flowing through the switching transistor MN1, the DC output voltage VOUT, and a clock signal CLK.

As described above, the capacitor CF included in the current-mode active capacitor 1115 can have a small capacitance, for example, 10 pF. However, the equivalent capacitance Ceq can be large, for example, 830 pF. Therefore, the current-mode active capacitor 1115 can be implemented in a semiconductor integrated circuit.

The frequency compensating circuit 1110 can detect the feedback voltage signal VFB, which is generated by dividing the DC output voltage VOUT via resistors RF1 and RF2. The frequency compensating circuit 1110 can also compensate for a frequency characteristic of the feedback voltage VFB. The compensating voltage signal VC can be compared with the first detecting voltage signal VSEN1 that corresponds to the current flowing through the switching transistor MN1 by the comparator 1130. The RS-type flip-flop 1140 can generate a pulse signal of which the pulse width is changed in response to the output signal of the comparator 1130 and the clock signal CLK. The output signal of the RS-type flip-flop 1140 can be buffered by the buffer 1150, and provided to a gate of the switching transistor MN1. The RS-type flip-flop 1140 can perform the function of generating a pulse signal having a pulse width that is changed according to the comparison of the compensating voltage signal VC and the first detecting voltage signal VSEN1. Other pulse width modulator (PWMs) may be used instead of the RS-type flip-flop 1140.

FIG. 10A and FIG. 10B illustrate waveforms of an output signal of a frequency compensating circuit in conventional circuits and in some of the above embodiments, respectively.

FIG. 10A illustrates simulated waveforms in existing frequency compensating circuits, created e.g. by replacing the frequency compensating circuit 1110 in the DC-DC converter 1000 of FIG. 9 by the conventional frequency compensating circuit 110 shown in FIG. 1.

FIG. 10B illustrates simulated waveforms in some of the above embodiments of the frequency compensating circuit 1110. The simulations were performed for the case when a load current was changed from 600 mA to 3 A at time T1, and a reference voltage VREF1, applied to the transconductance amplifier 1112, is changed from 1.15 V to 1.25 V at time T2.

As illustrated in FIG. 10A and FIG. 10B, a waveform of the output signal VC of the frequency compensating circuit 1110 that includes the current-mode active capacitor 1115 is similar to the waveform of the output signal VC of the existing frequency compensating circuit 110.

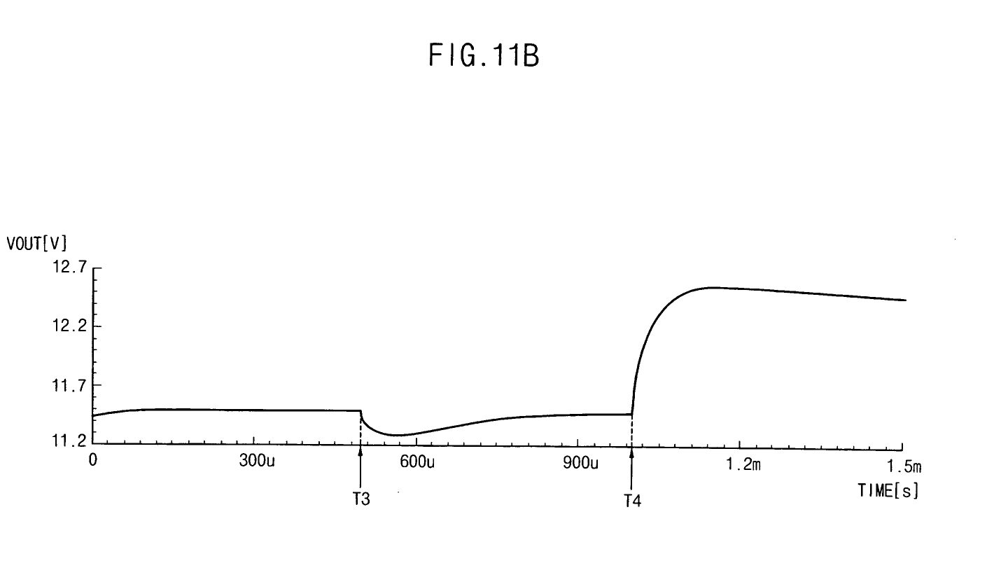

FIG. 11A and FIG. 11B illustrate waveforms of an output signal of a buck converter in conventional circuits and in some of the above embodiments, respectively.

FIG. 11A illustrates a waveform of a DC output voltage when the frequency compensating circuit 1110 in the DC-DC converter 1000 of FIG. 9 is replaced by the conventional frequency compensating circuit 110 shown in FIG. 1.

FIG. 11B illustrates a waveform of a DC output voltage of the DC-DC converter 1000 having the frequency compensating circuit 1110, shown in FIG. 9. The waveforms shown in FIG. 11A and FIG. 11B are simulation results for the case when a load current was changed from 600 mA to 3 A at time T3, and a reference voltage VREF1, applied to the transconductance amplifier 1112, was changed from 1.15 V to 1.25 V at time T4.

As illustrated in FIG. 11A and FIG. 11B, a waveform of a DC output voltage VOUT of the DC-DC converter 1000 that includes the frequency compensating circuit 1110 is similar to the waveform of the DC output voltage VOUT of the DC-DC converter 1000 that includes the frequency compensating circuit 110. Correspondingly, the transient response and the step response of the frequency compensating circuit 1110, which includes one of the above embodiments of current-mode active capacitor, behaves similarly to the frequency compensating circuit 1110, which includes a conventional compensating capacitor.

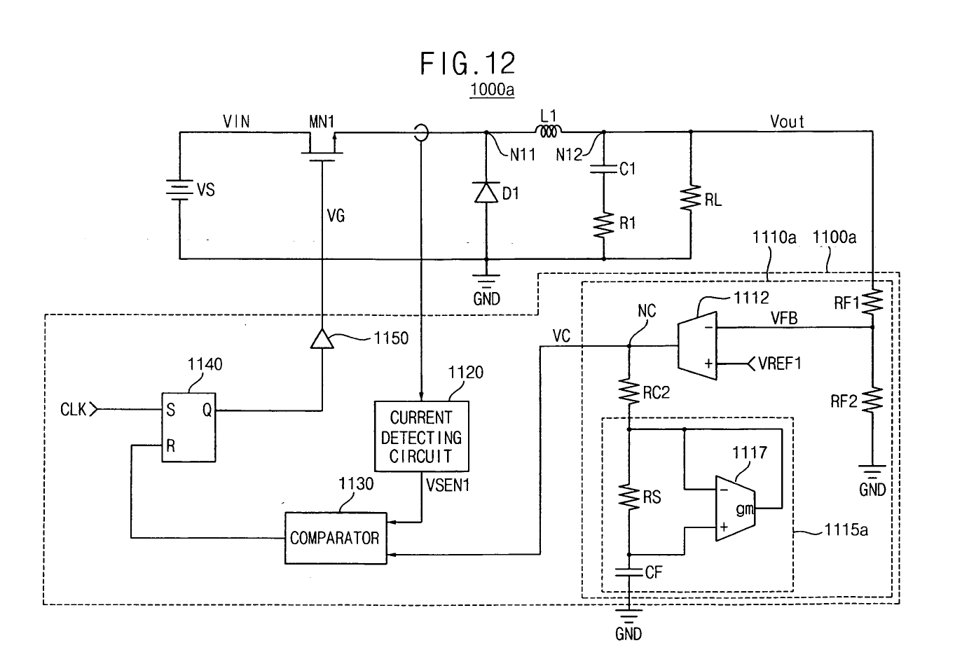

FIG. 12 is a DC-DC converter 100a, which can include the frequency compensating circuit of FIG. 8. The DC-DC converter 1000a can include the control circuit 1100a, labeled as 200 in FIG. 8, instead of the control circuit 1100, shown in FIG. 9. The control circuit 1100a can include the frequency compensating circuit 1110a having the current-mode active capacitor 1115a. The current-mode active capacitor 1115a can have a structure analogous to the structure of the current-mode active capacitor 10a shown in FIG. 5. As described above, the current-mode active capacitor 10a shown in FIG. 5 may have a similar characteristic as the current-mode active capacitor 10 shown in FIG. 3. Further, both of the current-mode active capacitor 10a shown in FIG. 5 and the current-mode active capacitor 10 shown in FIG. 3 may have the equivalent circuit shown in FIG. 4.

The DC-DC converter 1000a shown in FIG. 12 can operate in a way similar to the DC-DC converter 1000 shown in FIG. 9.

As described above, embodiments of the current-mode active capacitor can have a capacitance multiplying effect. That is, embodiments of the current-mode active capacitor, having a small capacitance, may be characterized via an equivalent capacitor having a large capacitance. Frequency compensating circuits that include the above embodiments of the current-mode active capacitor may have a frequency characteristic that is similar to the frequency characteristic of the frequency compensating circuit that includes a large compensating capacitor, even though they employ a low capacitance compensating capacitor. Correspondingly, embodiments of the frequency compensating circuit may occupy a small area in a semiconductor integrated circuit because the frequency compensating circuit uses a capacitor having a small capacitance. Therefore, it is easy to include embodiments of the frequency compensating circuit in the semiconductor integrated circuit. Embodiments of the frequency compensating circuit, which include a current-mode active capacitor, can be particularly useful in hand-held electronic systems, where space for parts is limited.

While examples and their advantages have been described in relation to certain embodiments, it should be understood that various changes, substitutions and alterations may be made without departing from the scope of the invention, which is defined only by the attached claims.

What is claimed is:

1. A current-mode active capacitor in a frequency compensating circuit for a DC-DC converter, comprising:
a first capacitor coupled between a first node and a second node;
a first resistor coupled between the second node and a third node; and
a transconductance amplifier configured to have a first input terminal coupled to the second node, a second input terminal coupled to the third node, and an output terminal coupled to the first node.

2. The current-mode active capacitor of claim 1, wherein a ground voltage is applied to the third node.

3. The current-mode active capacitor of claim 1, wherein an equivalent circuit of the current-mode active capacitor is configured to have an equivalent capacitor with a capacitance of (1+gm·RS) CF, and an equivalent resistor with a resistance of RS/(1+gm·RS), wherein gm denotes a transconductance of the transconductance amplifier, RS denotes a resistance of the first resistor, and CF denotes a capacitance of the first capacitor.

4. A current-mode active capacitor comprising:
a first resistor coupled between a first node and a second node;
a first capacitor coupled between the second node and a low supply voltage; and
a transconductance amplifier configured to have a first input terminal coupled to the first node, a second input terminal coupled to the second node, and an output terminal coupled to the first node.

5. The current-mode active capacitor of claim 4, wherein an equivalent circuit of the current-mode active capacitor is configured to have an equivalent capacitor with a capacitance of (1+gm·RS) CF, and an equivalent resistor with a resistance of RS/(1+gm·RS), wherein gm denotes a transconductance of the transconductance amplifier, RS denotes a resistance of the first resistor, and CF denotes a capacitance of the first capacitor.

6. A frequency compensating circuit comprising:
a first transconductance amplifier configured to amplify a feedback voltage signal in a current mode to provide the amplified voltage to a first node; and
a current-mode active capacitor coupled to the first node.

7. The frequency compensating circuit of claim 6 further comprising:
a resistor coupled between the first node and the current-mode active capacitor.

8. The frequency compensating circuit of claim 6, wherein the current-mode active capacitor comprises:
a first capacitor coupled between a first node and a second node;
a first resistor coupled between the second node and a third node; and
a transconductance amplifier configured to have a first input terminal coupled to the second node, a second input terminal coupled to the third node, and an output terminal coupled to the first node.

9. The frequency compensating circuit of claim 8, wherein an equivalent circuit of the current-mode active capacitor is configured to have an equivalent capacitor and an equivalent resistor, a capacitance of the equivalent capacitor being (1+gm·RS) CF and an equivalent resistor with a resistance of RS/(1+gm·RS), wherein gm denotes a transconductance of the transconductance amplifier, RS denotes a resistance of the first resistor, and CF denotes a capacitance of the first capacitor.

10. The frequency compensating circuit of claim 8, wherein a ground voltage is applied to the third node.

11. The frequency compensating circuit of claim 6, wherein the current-mode active capacitor comprises:
a first resistor coupled between a first node and a second node;
a first capacitor coupled between the second node and a low supply voltage; and
a transconductance amplifier configured to have a first input terminal coupled to the first node, a second input terminal coupled to the second node, and an output terminal coupled to the first node.

12. The frequency compensating circuit of claim 11, wherein an equivalent circuit of the current-mode active capacitor is configured to have an equivalent capacitor and an equivalent resistor, a capacitance of the equivalent capacitor being (1+gm·RS) CF and an equivalent resistor with a resistance of RS/(1+gm·RS), wherein gm denotes a transconductance of the transconductance amplifier, RS denotes a resistance of the first resistor, and CF denotes a capacitance of the first capacitor.

13. The frequency compensating circuit of claim 6, wherein the feedback voltage signal is generated based on an output signal of a DC-DC converter.

14. A control circuit comprising:
a frequency compensating circuit configured to have a current-mode active capacitor and configured to amplify a feedback voltage signal to generate a compensating voltage signal and provide the compensating voltage signal to a first node;
a current detecting circuit configured to detect a current flowing through a switching transistor to generate a first detecting voltage signal;
a comparator configured to compare the compensating voltage signal with the first detecting voltage signal to generate a comparing signal; and
a pulse-width modulating circuit configured to generate a gate driving signal based on a clock signal and the comparing signal.

15. The control circuit of claim 6, wherein the pulse-width modulating circuit is configured to have a flip-flop.

16. The control circuit of claim 6 further comprising:
a buffer configured to buffer an output signal of the pulse-width modulating circuit to generate the gate driving signal.

17. The control circuit of claim 14, wherein the frequency compensating circuit comprises:
a first transconductance amplifier configured to amplify a feedback voltage signal in a current mode to provide the amplified voltage to a first node; and
a current-mode active capacitor coupled to the first node.

18. The control circuit of claim 17 further comprising:
a resistor coupled between the first node and the current-mode active capacitor.

19. The control circuit of claim 17, wherein the current-mode active capacitor comprises:
a first capacitor coupled between a first node and a second node;
a first resistor coupled between the second node and a third node; and
a transconductance amplifier configured to have a first input terminal coupled to the second node, a second input terminal coupled to the third node, and an output terminal coupled to the first node.

20. The control circuit of claim 19, wherein an equivalent circuit of the current-mode active capacitor is configured to have an equivalent capacitor and an equivalent resistor, a capacitance of the equivalent capacitor being (1+gm·RS) CF and an equivalent resistor with a resistance of RS/(1+gm·RS), wherein gm denotes a transconductance of the transconductance amplifier, RS denotes a resistance of the first resistor, and CF denotes a capacitance of the first capacitor.

21. The control circuit of claim 19, wherein a ground voltage is applied to the third node.

22. The control circuit of claim 17, wherein the current-mode active capacitor comprises:
a first resistor coupled between a first node and a second node;
a first capacitor coupled between the second node and a low supply voltage; and
a transconductance amplifier configured to have a first input terminal coupled to the first node, a second input terminal coupled to the second node, and an output terminal coupled to the first node.

23. The control circuit of claim 14, wherein the feedback voltage signal is generated based on an output signal of a DC-DC converter.

24. A DC-DC converter comprising:
an input node to which a DC input voltage is applied;
a switching transistor coupled between the input node and a first node, and configured to be driven in response to a gate driving signal;
a diode configured to have a cathode coupled to the first node and an anode coupled to a first supply voltage;
an inductor coupled between the first node and an output node;
a first capacitor coupled between the output node and the first supply voltage; and
a control circuit including a frequency compensating circuit that has a current-mode active capacitor, the control circuit generating the gate driving signal in response to a current flowing through the switching transistor, a voltage of the output node, and a clock signal.

25. The DC-DC converter of claim 24, wherein the control circuit comprises:
a frequency compensating circuit configured to have a current-mode active capacitor and configured to amplify a feedback voltage signal to generate a compensating voltage signal and provide the compensating voltage signal to a first node;
a current detecting circuit configured to detect a current flowing through the switching transistor to generate a first detecting voltage signal;
a comparator configured to compare the compensating voltage signal with the first detecting voltage signal to generate a comparing signal; and
a pulse-width modulating circuit configured to generate a gate driving signal based on a clock signal and the comparing signal.

26. The DC-DC converter of claim 25, wherein the pulse-width modulating circuit is configured to have a flip-flop.

27. The DC-DC converter of claim 25, wherein the control circuit further comprises:
a buffer configured to buffer an output signal of the pulse-width modulating circuit to generate the gate driving signal.

28. A method of frequency compensation, the method comprising:
amplifying a feedback voltage signal in a current mode to provide the amplified voltage to a first node;
generating an active capacitance in the current mode; and
providing the active capacitance to the first node.

29. A method of driving gates, the method comprising:
generating an active capacitance in the current mode;
amplifying a feedback voltage signal to generate a compensating voltage signal based on the active capacitance;
detecting a current flowing through a switching transistor to generate a first detecting voltage signal;
comparing the compensating voltage signal with the first detecting voltage signal to generate a comparing signal; and
generating a gate driving signal based on a clock signal and the comparing signal.
